(19) United States
(12) Patent Application Publication
(10) Pub. No.: US 2014/0306251 A1
(43) Pub. Date: Oct. 16, 2014

(54) PATTERNED LIGHT EMITTING ELEMENT SUBSTRATE

(71) Applicant: PHECDA TECHNOLOGY CO. LTD., Taipei City (TW)

(72) Inventor: YONG-FA HUANG, Zhunan Township, Miaoli County (TW)

(21) Appl. No.: 13/910,447

(22) Filed: Jun. 5, 2013

(30) Foreign Application Priority Data
Apr. 12, 2013 (TW) 102206774

(51) Int. Cl. H01L 33/22

(52) U.S. Cl. CPC H01L 33/22
USPC 257/98

(57) ABSTRACT

Disclosed is a patterned light-emission element substrate including a surface consisted of a plurality of cones, and the surface of each cone is roughened by a wet etch roughening treatment to produce a rough surface.

### CROSS-REFERENCE TO RELATED APPLICATION

This application claims priority from Taiwan Patent Application No. 102206774, filed on Apr. 12, 2013 in Taiwan Intellectual Property Office, the contents of which are hereby incorporated by reference in their entirety.

### FIELD OF THE INVENTION

The present invention relates to a patterned light emitting element substrate, and more particularly to the patterned light emitting element substrate having a rough surface, and a light emitting element using this substrate.

### BACKGROUND OF THE INVENTION

In general, most manufacturers use a patterned sapphire substrate (PSS) as the substrate of a light emitting element to achieve the effects of improving brightness, reducing dislocation density, and obtaining good light extraction efficiency.

However, patterns of conventional patterned light emitting element substrates usually have smooth surfaces and a limited angular range of the surfaces, and the light emitted from the light emitting element often has reflections within a specific angular range.

Therefore, a method of reducing the limitation of the angular range of the surface is required to overcome the problems of light diffusion and brightness.

### SUMMARY OF THE INVENTION

In view of the aforementioned problems of the prior art, it is a primary objective of the present invention to provide a patterned light emitting element substrate and a light emitting element using the substrate and a method for reducing the limitation of the angular range of the surfaces is required to improve the light diffusion and brightness.

To achieve the aforementioned objective, the present invention provides a patterned light emitting element substrate comprising a surface consisted of a plurality of cones, and the surface of each of the cones being roughened by a wet etch roughening treatment to produce a rough surface.

Wherein, the patterned light emitting element substrate is a sapphire substrate or a silicon substrate.

Wherein, the wet etching process is a chemical etching process.

Wherein, the cones are distributed uniformly.

Wherein, the cones are not contacted with one another.

To achieve the aforementioned objective, the present invention further provides a light emitting element, comprising: a patterned substrate, further comprising a surface consisted of a plurality of cones, and the surface of each of the cones being roughened by a wet-etch roughening treatment to produce a rough surface; a first semiconductor layer, disposed on the patterned substrate; a light emitting layer, disposed on the first semiconductor layer; a second semiconductor layer, disposed on the light emitting layer; a first ohmic electrode, contacted with the first semiconductor layer; and a second ohmic electrode, contacted with the second semiconductor layer.

Wherein, the patterned substrate is a sapphire substrate or a silicon substrate.

Wherein, the wet etching process is a chemical etching process.

Wherein, the cones are distributed uniformly.

Wherein, the cones are not contacted with one another.

### BRIEF DESCRIPTION OF THE DRAWINGS

FIG. 1 is a schematic view of a wet etching process of a patterned light emitting element substrate of the present invention;

FIG. 2 is a schematic view of a rough surface of a cone included in a patterned light emitting element substrate of the present invention; and

FIG. 3 is a schematic view of a light emitting element of the present invention.

### DESCRIPTION OF THE PREFERRED EMBODIMENTS

The technical characteristics, contents, advantages and effects of the present invention will become apparent from the following detailed description taken with the accompanying drawing. The term “and/or” includes one, a combination, or all of the related elements, and this term is similar to the expression of the term “at least one” of a series of elements, so that the whole series can be modified instead of modifying each element in the series.

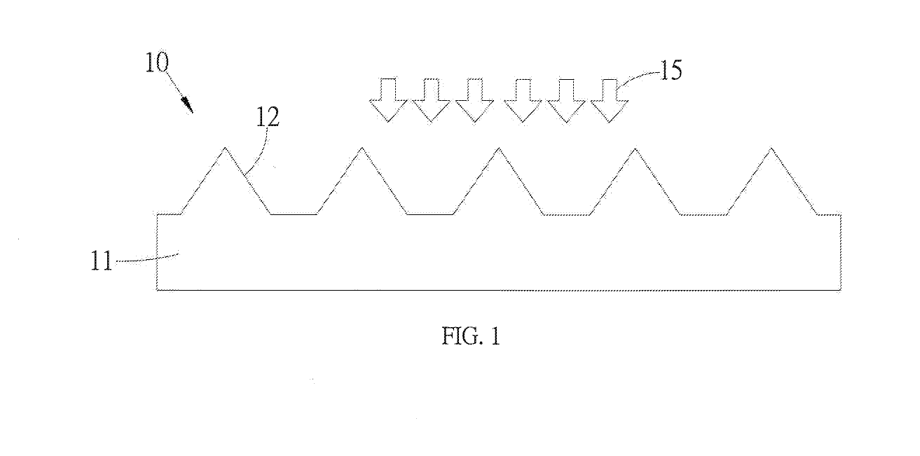

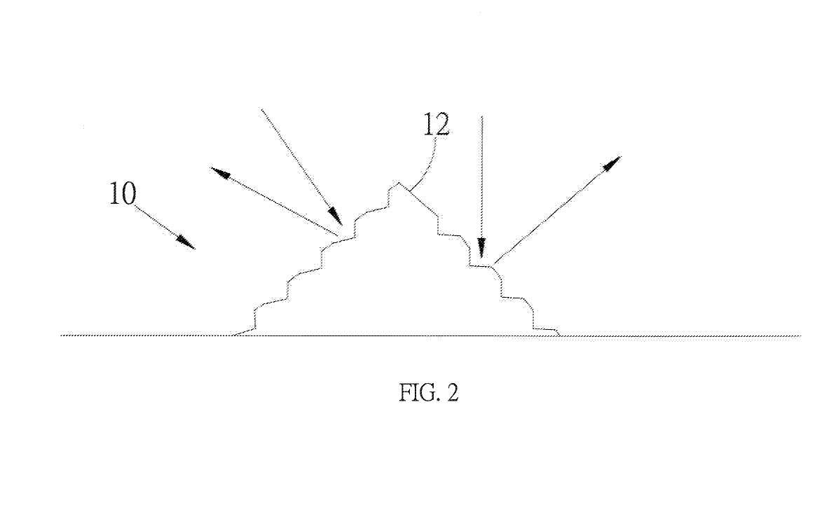

With reference to FIG. 1 for a schematic view of a wet etching process of a patterned light emitting element substrate of the present invention and FIG. 2 for a schematic view of a rough surface of a cone included in a patterned light emitting element substrate of the present invention, the patterned light emitting element substrate 10 as shown in FIG. 1 comprises a substrate body 11 and a surface consisted of a plurality of cones 12, wherein the patterned light emitting element substrate 10 is a sapphire substrate or a silicon substrate. The cones 12 are distributed uniformly on the substrate body 11 or distributed in a specific way according to the actual requirements. Wherein, the cones 12 are not contacted with one another.

The cones 12 adopt a wet etching process 15 for a roughening treatment to produce a rough surface on each cone 12 as shown in FIG. 2. The rough surface of each cone 12 provides a better diffusion effect to improve the light emitting brightness of the light emitting element of the present invention.

The wet etch method adopted in a preferred embodiment of the present invention is a common chemical etching process.

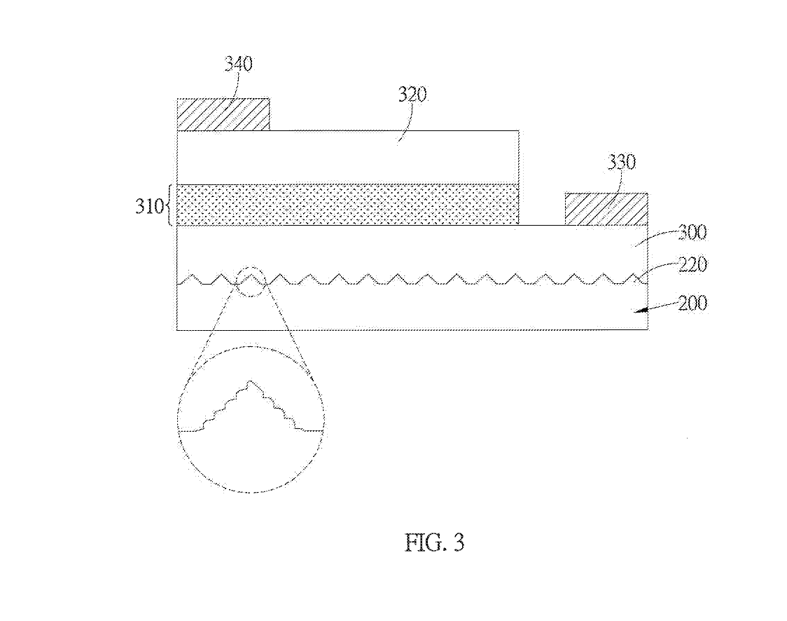

With reference to FIG. 3 for a schematic view of a light emitting element of a patterned substrate 200 which is a light emitting diode (LED) in this preferred embodiment of the present invention, the light emitting diode comprises a patterned substrate 200, a first semiconductor layer 300 disposed on the patterned substrate 200, a light emitting layer 310 disposed on the first semiconductor layer 300, a second semiconductor layer 320 disposed on the light emitting layer 310, a first ohmic electrode 330 contacted with the first semiconductor layer 300, and a second ohmic electrode 340 contacted with the second semiconductor layer 320. The patterned substrate 200 comprises a surface consisted of a plurality of cones 220, and the surface of each cone 220 is roughened by a wet etch roughening treatment to produce a rough surface.

The rough surface of each cone 220 provides a better diffusion effect for the light emitted from the light emitting layer 310 towards the patterned substrate 200 to improve the light emitting brightness of the light emitting diode of the present invention.

Wherein, the patterned substrate 200 is a sapphire substrate or a silicon substrate. The cones 220 are distributed uniformly on the patterned substrate 200 or distributed in a specific way. The cones 12 are not contacted with one another.

Wherein, the first semiconductor layer 300, the light emitting layer 310 and the second semiconductor layer 320 are made of Group III-V based semiconductors such as gallium nitride based semiconductors. The first and second ohmic electrodes 330, 340 are made of at least one alloy or multilayer film selected from the collection of nickel, lead, cobalt, iron, titanium, copper, rhodium, gold, ruthenium, tungsten, zirconium, molybdenum, tantalum, silver, and oxides and nitrides thereof. In addition, the first and second ohmic electrodes 330, 340 are made of at least one alloy or multilayer film selected from the collection of rhodium, iridium, silver and aluminum.

What is claimed is:

1. A patterned light emitting element substrate, comprising a surface consisted of a plurality of cones, and the surface of each of the cones being roughened by a wet etch roughening treatment to produce a rough surface.

2. The patterned light emitting element substrate of claim 1, wherein the patterned light emitting element substrate is a sapphire substrate or a silicon substrate.

3. The patterned light emitting element substrate of claim 1, wherein the wet etching process is a chemical etching process.

4. The patterned light emitting element substrate of claim 1, wherein the cones are distributed uniformly.

5. The patterned light emitting element substrate of claim 4, wherein the cones are not contacted with one another.

6. A light emitting element, comprising:
a patterned substrate, comprising a surface consisted of a plurality of cones, and the surface of each of the cones being roughened by a wet-etch roughening treatment to produce a rough surface,
a first semiconductor layer, disposed on the patterned substrate;
a light emitting layer, disposed on the first semiconductor layer;
a second semiconductor layer, disposed on the light emitting layer;
a first ohmic electrode, contacted with the first semiconductor layer; and
a second ohmic electrode, contacted with the second semiconductor layer.

7. The patterned light emitting element substrate of claim 6, wherein the patterned substrate is a sapphire substrate or a silicon substrate.

8. The patterned light emitting element substrate of claim 6, wherein the wet etching process is a chemical etching process.

9. The patterned light emitting element substrate of claim 6, wherein the cones are distributed uniformly.

10. The patterned light emitting element substrate of claim 9, wherein the cones are not contacted with one another.
